(19) United States
(12) Patent Application Publication
(10) Pub. No.: US 2026/0142635 A1
(43) Pub. Date: May 21, 2026

(54) FILTER AND PREPARATION METHOD THEREFOR, AND ELECTRONIC DEVICE

(71) Applicants: Beijing BOE Sensor Technology Co., Ltd., Beijing (CN); BOE Technology Group Co., Ltd., Beijing (CN); Beijing BOE Technology Development Co., Ltd., Beijing (CN)

(72) Inventors: Yingying ZHAO, Beijing (CN); Yue LI, Beijing (CN); Yuelei XIAO, Beijing (CN); Qichang AN, Beijing (CN); Huiying LI, Beijing (CN); Yifan WU, Beijing (CN); Can ZHANG, Beijing (CN); Shuang XU, Beijing (CN); Kuili REN, Beijing (CN); Biqi LI, Beijing (CN)

(21) Appl. No.: 19/120,233

(22) PCT Filed: Jul. 9, 2024
(86) PCT No.: PCT/CN2024/104375

§ 371 Date: Apr. 11, 2025

(30) Foreign Application Priority Data
Aug. 9, 2023 (CN) 202311001494.0

(51) Int. Cl. H03H 1/00; H03H 3/00

(52) U.S. Cl. CPC H03H 1/00; H03H 3/00; H03H 2001/0085

(57) ABSTRACT

Provided are a filter and a preparation method therefor, and an electronic device. The filter comprises a base substrate, which is provided with a conductive column, wherein a first structure layer is provided on a first surface of the base substrate, and a second structure layer, a first insulating layer, a lead layer, a second insulating layer and a pad layer are provided on a second surface of the base substrate. The first structure layer and the second structure layer each comprise a connecting electrode connected to the conductive column, and the second structure layer further comprises a capacitor structure; the lead layer comprises at least one lead, wherein the lead is connected to the capacitor structure; the pad layer comprises at least one pad, wherein the pad is connected to the lead; and the materials of the first insulating layer and the second insulating layer comprise an organic material.

### CROSS-REFERENCE TO RELATED APPLICATION

The present application is a U.S. National Phase Entry of International Application No. PCT/CN2024/104375 having an international filing date of Jul. 9, 2024, which claims priority of Chinese Patent Application No. 202311001494.0, filed to the CNIPA on Aug. 9, 2023 and entitled “Filter and Preparation Method Therefor, and Electronic Device”. Contents of the above-identified applications are incorporated into the present application by reference.

### TECHNICAL FIELD

The present disclosure relates to, but is not limited to, the field of semiconductor technologies, in particular to a filter, a preparation method therefor and an electronic device.

### BACKGROUND

As an important component of a communication terminal, filters can solve a problem of mutual interference in a process of signal transmission and improve spectrum availability. With development of mobile communication technologies, mobile communication systems require filters with small area, high performance and good consistency. An Integrated Passive Device (IPD) is widely used in Radio Frequency (RF) front-end chips in wireless communication devices because of its superior independent passive component characteristics.

### SUMMARY

The following is a summary of subject matters described herein in detail. This summary is not intended to limit the protection scope of claims.

In one aspect, the present disclosure provides a filter. The filter includes a base substrate. A conductive column penetrating through the base substrate in a thickness direction is provided in the base substrate, and a first structure layer is provided on a first surface of the base substrate. A second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate are provided on a second surface of the base substrate. The first surface and the second surface are surfaces opposite to each other. The first structure layer and the second structure layer each include a connecting electrode connected to the conductive column, the second structure layer further includes a capacitor structure, and the lead layer includes at least one lead. The lead is connected to the capacitor structure, the pad layer includes at least one pad, and the pad is connected to the lead. Materials of the first insulating layer and the second insulating layer include an organic material.

In an exemplary implementation, the capacitor structure includes a first plate provided on the second surface of the base substrate, a capacitor dielectric layer provided on a side of the first plate away from the base substrate, and a second plate provided on a side of the capacitor dielectric layer away from the base substrate. An orthographic projection of the second plate on the base substrate is within a range of an orthographic projection of the capacitor dielectric layer on the base substrate.

In an exemplary implementation, the orthographic projection of the capacitor dielectric layer on the base substrate is within a range of an orthographic projection of the first plate on the base substrate.

In an exemplary implementation, areas of the first plate, the capacitor dielectric layer, and the second plate sequentially decrease along a direction away from the base substrate.

In an exemplary implementation, in a plane parallel to the base substrate, there is a first distance between an edge of the first plate and an edge of the capacitor dielectric layer in at least one direction. The first distance is greater than or equal to 50 nm.

In an exemplary implementation, in a plane parallel to the base substrate, there is a second distance between an edge of the capacitor dielectric layer and an edge of the second plate in at least one direction. The second distance is greater than or equal to 50 nm.

In an exemplary implementation, the first plate includes a seed layer provided on the second surface of the base substrate and a conductive layer provided on a side of the seed layer away from the base substrate. The connecting electrode in the second structure layer includes a seed layer provided on the second surface of the base substrate and a conductive layer provided on a side of the seed layer away from the base substrate.

In an exemplary implementation, the seed layer includes a two-layer structure of a titanium layer and a copper layer, and a thickness of the titanium layer is 10 nm to 200 nm.

In an exemplary implementation, the first plate and the connecting electrode in the second structure layer are provided in a same layer and are synchronously formed by a same patterning process.

In an exemplary implementation, an orthographic projection of the connecting electrode in the second structure layer on the base substrate is within a range of the orthographic projection of the capacitor dielectric layer on the base substrate.

In an exemplary implementation, the first plate includes a seed layer provided on the second surface of the base substrate, a conductive layer provided on a side of the seed layer away from the base substrate, and a conductive protection layer provided on a side of the conductive layer away from the base substrate. The connecting electrode in the second structure layer includes a seed layer provided on the second surface of the base substrate, a conductive layer provided on a side of the seed layer away from the base substrate, and a conductive protection layer provided on a side of the conductive layer away from the base substrate.

In an exemplary implementation, the seed layer includes a two-layer structure of a titanium layer and a copper layer, and a material of the conductive protection layer includes titanium, and a thickness of the titanium layer is 10 nm to 200 nm.

In an exemplary implementation, the first plate and the connecting electrode are provided in a same layer and are synchronously formed by a same Damascene process.

In an exemplary implementation, the first plate and the connecting electrode are respectively formed by different patterning processes, and a thickness of the first plate is less than a thickness of the connecting electrode.

In an exemplary implementation, the second plate adopts a stacked structure of a titanium layer/copper layer/titanium layer, or adopts a stacked structure of a titanium layer/aluminum layer/titanium layer. A thickness of the titanium layer is 30 nm to 50 nm, and a thickness of the copper layer or the aluminum layer is 200 nm to 400 nm.

In an exemplary implementation, the connecting electrode in the first structure layer includes a seed layer and a conductive layer provided on a side of the seed layer away from the base substrate, the seed layer includes a two-layer structure of a titanium layer and a copper layer, and a thickness of the titanium layer is 10 nm to 200 nm.

In an exemplary implementation, the first structure layer further includes a protection layer provided on a side of the connecting electrode away from the base substrate, a material of the protection layer includes an organic material, and a thickness of the protection layer is 1 μm to 10 μm.

In an exemplary implementation, a cross-sectional shape of the conductive column includes a column shape, a tapered shape, or an hourglass shape in a direction perpendicular to the base substrate.

In another aspect, the present disclosure further provides an electronic device including the foregoing filter.

In a further aspect, the present disclosure further provides a preparation method for a filter, including: forming a metallized through-hole base substrate, wherein a conductive column penetrating through the base substrate in a thickness direction is provided in the base substrate; and forming a first structure layer on a first surface of the base substrate, and forming a second structure layer, a first insulating layer provided on a side of the second structure layer away from the base substrate, a lead layer provided on a side of the first insulating layer away from the base substrate, a second insulating layer provided on a side of the lead layer away from the base substrate and a pad layer provided on a side of the second insulating layer away from the base substrate on a second surface of the base substrate. The first surface and the second surface are surfaces opposite to each other, the first structure layer and the second structure layer each include a connecting electrode connected to the conductive column, and the second structure layer further includes a capacitor structure. The lead layer includes at least one lead, the lead is connected to the capacitor structure, the pad layer includes at least one pad, and the pad is connected to the lead. Materials of the first insulating layer and the second insulating layer include an organic material.

In an exemplary implementation, the capacitor structure includes a first plate provided on the second surface of the base substrate, a capacitor dielectric layer provided on a side of the first plate away from the base substrate, and a second plate provided on a side of the capacitor dielectric layer away from the base substrate. An orthographic projection of the second plate on the base substrate is within a range of an orthographic projection of the capacitor dielectric layer on the base substrate, and the orthographic projection of the capacitor dielectric layer on the base substrate is within a range of an orthographic projection of the first plate on the base substrate.

In an exemplary implementation, the first plate and the connecting electrode in the second structure layer are provided in a same layer and are synchronously formed by a same patterning process.

In an exemplary implementation, the first plate and the connecting electrode in the second structure layer are provided in a same layer and are synchronously formed by a same Damascene process.

In an exemplary implementation, the first plate and the connecting electrode in the second structure layer are formed by different patterning processes, and a thickness of the first plate is less than a thickness of the connecting electrode in the second structure layer.

In an exemplary implementation, the capacitor dielectric layer and the second plate are formed using a patterning process including a dry etching process, respectively.

In a further aspect, the present disclosure further provides a preparation method for a filter, including: forming a metallized blind via base substrate, wherein a conductive column not penetrating through the base substrate in a thickness direction is provided in the base substrate; forming a second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate on a second surface of the base substrate; flipping the base substrate and thinning a first surface of the base substrate until the conductive column is exposed, wherein the first surface and the second surface are surfaces opposite to each other; and forming a first structure layer on the first surface of the base substrate.

The first structure layer and the second structure layer each include a connecting electrode connected to the conductive column, and the second structure layer further includes a capacitor structure. The lead layer includes at least one lead, the lead is connected to the capacitor structure, the pad layer includes at least one pad, and the pad is connected to the lead. Materials of the first insulating layer and the second insulating layer include an organic material.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a structure of a filter according to an exemplary embodiment of the present disclosure;

FIGS. 2A and 2B are schematic diagrams of the formation of a metallized TGV base substrate of a filter according to the present disclosure;

FIGS. 3A and 3B are schematic diagrams of the formation of a first structure layer of a filter according to the present disclosure;

FIG. 4 is a schematic diagram of a filter after forming a second conductive layer according to the present disclosure;

FIG. 5 is a schematic diagram of a filter after forming a surface insulating layer according to the present disclosure;

FIG. 6 is a schematic diagram of a filter after forming a second plate according to the present disclosure;

FIG. 7 is a schematic diagram of a filter after forming a first insulating layer according to the present disclosure;

FIG. 8 is a schematic diagram of a filter after forming a lead layer according to the present disclosure;

FIG. 9 is a schematic diagram of a filter after forming a second insulating layer according to the present disclosure;

FIG. 10 is a schematic diagram of a structure of another filter according to an exemplary embodiment of the present disclosure;

FIG. 11 is a schematic cross-sectional structural view of a capacitor structure according to an exemplary embodiment of the present disclosure;

FIGS. 12A to 12E are schematic diagrams of the formation of a first structure layer and a second conductive layer of another filter according to the present disclosure;

FIG. 13 is a schematic diagram of another filter after forming a capacitor dielectric layer according to the present disclosure;

FIG. 14 is a schematic diagram of another filter after forming a second plate according to the present disclosure;

FIG. 15 is a schematic diagram of a planar structure of a capacitor structure according to an exemplary embodiment of the present disclosure;

FIG. 16 is a schematic diagram of a structure of yet another filter according to an exemplary embodiment of the present disclosure;

FIGS. 17A and 17B are schematic diagrams of the formation of a metallized BGV base substrate of yet another filter according to the present disclosure;

FIGS. 18A to 18D are schematic diagrams of the formation of a second conductive layer of yet another filter according to the present disclosure;

FIG. 19 is a schematic diagram of yet another filter after forming a capacitor dielectric layer according to the present disclosure;

FIG. 20 is a schematic diagram of yet another filter after forming a second plate according to the present disclosure;

FIG. 21 is a schematic diagram of yet another filter after forming a pad layer according to the present disclosure;

FIGS. 22A and 22B are schematic diagrams of yet another filter after forming a first conductive layer according to the present disclosure; and

FIG. 23 is a schematic diagram of a structure of yet another filter according to an exemplary embodiment of the present disclosure.

Reference signs are described as follows.

| | | |
|---|---|---|
| 10-base substrate; | 11-protection layer; | 12-surface insulating layer |
| 31-first conductive column; | 32-second conductive column; | 41-first connecting electrode; |
| 42-second connecting electrode; | 43-third connecting electrode; | 44-fourth connecting electrode; |
| 45-fifth connecting electrode; | 51-first plate; | 52-second plate; |
| 53-capacitor dielectric layer; | 61-first insulating layer; | 62-second insulating layer; |
| 71-first lead; | 72-second lead; | 73-third lead; |
| 81-first pad | 82-second pad; | 83-third pad |
| 91-first through-hole; | 92-second through-hole; | 93-first blind via |
| 94-second blind via; | 100-first structure layer; | 200-second structure layer. |

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. The drawings described in the present disclosure are only schematic diagrams of structures, and one implementation of the present disclosure is not limited to shapes or numerical values or the like shown in the drawings.

Ordinal numerals “first”, “second”, “third”, and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In the present disclosure, “about” means that a boundary is not defined so strictly and numerical values within process and measurement error ranges are allowed.

With the development of 5G technologies, 5G frequency bands continue to increase, and radio frequency front-ends are facing growing demand. In the 5G radio frequency front-end, the filter device is one of the core components, and the number of filters in each 5G mobile phone is at least 50. In order to meet the needs of miniaturization, high integration, high frequency bandwidth and low cost and the like, Through Glass Via (TGV) technology has gradually become a feasible technology for passive filter (LC filter) design. The through glass via (TGV) technology refers to making a through-hole on glass substrate, filling a metal material in the through-hole, and electrically connecting functional structures located on an upper surface of the glass substrate with functional structures located on a lower surface of the glass substrate. Since glass materials have the advantages of good high-frequency characteristics, good insulation, low loss, and excellent Q value of glass core 3D inductance and the like, compared with silicon (Si)-based IPD, TGV-based IPD can avoid high microwave loss of devices due to the poor insulation from silicon-based. Compared with low-temperature co-fired ceramics (LTCC) and IPD filters based on high resistance silicon (HRSi), the TGV-based IPD have the characteristics of compact size, low insertion loss, good high-frequency performance and easy packaging and the like, which can achieve better electric performance and play important roles in 5G NR and WiFi 6.

The present disclosure provides a passive filter. The passive filter includes a base substrate. A conductive column penetrating through the base substrate in a thickness direction is provided in the base substrate. A first structure layer is provided on a first surface of the base substrate. A second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate are provided on a second surface of the base substrate. The first surface and the second surface are surfaces opposite to each other. The first structure layer and the second structure layer each include a connecting electrode connected to the conductive column, the second structure layer further includes a capacitor structure, and the lead layer includes at least one lead. The lead is connected to the capacitor structure, the pad layer includes at least one pad, and the pad is connected to the lead. Materials of the first insulating layer and the second insulating layer include an organic material.

In an exemplary implementation, a thickness of the first insulating layer and a thickness of the second insulating layer may be about 1 μm to 10 μm.

In an exemplary implementation, the capacitor structure includes a first plate provided on the second surface of the base substrate, a capacitor dielectric layer provided on a side of the first plate away from the base substrate, and a second plate provided on a side of the capacitor dielectric layer away from the base substrate. An orthographic projection of the second plate on the base substrate is within a range of an orthographic projection of the capacitor dielectric layer on the base substrate, and the orthographic projection of the capacitor dielectric layer on the base substrate is within a range of an orthographic projection of the first plate on the base substrate.

In an exemplary implementation, areas of the first plate, the capacitor dielectric layer, and the second plate sequentially decrease along a direction away from the base substrate.

In an exemplary implementation, in a plane parallel to the base substrate, there is a first distance between an edge of the first plate and an edge of the capacitor dielectric layer in at least one direction. The first distance is greater than or equal to 50 nm.

In an exemplary implementation, in a plane parallel to the base substrate, there is a second distance between an edge of the capacitor dielectric layer and an edge of the second plate in at least one direction. The second distance is greater than or equal to 50 nm.

FIG. 1 is a schematic diagram of a structure of a filter according to an exemplary embodiment of the present disclosure. As shown in FIG. 1, a main body structure of a filter according to an exemplary embodiment of the present disclosure may include a base substrate 10, a first structure layer 100 and a second structure layer 200. The first structure layer 100 may be provided on a first surface of the base substrate 10, the second structure layer 200 may be provided on a second surface of the base substrate 10, and the first surface and the second surface are two surfaces of the base substrate 10 that are opposite to each other.

In an exemplary implementation, a plurality of conductive columns are embedded in the base substrate 10. The plurality of conductive columns penetrate through the base substrate 10 in a thickness direction, so that corresponding electrodes in the first structure layer 100 and the second structure layer 200 can be connected to each other by the plurality of conductive columns.

In an exemplary implementation, the plurality of conductive columns may at least include a first conductive column 31 and a second conductive column 32, and structures of the two conductive columns may be substantially the same. A shape of the conductive columns may be circular or elliptical in a plane parallel to the base substrate, and a cross-sectional shape of the conductive columns may be an hourglass shape in a plane perpendicular to the base substrate.

In an exemplary implementation, the first structure layer 100 may at least include a first connecting electrode 41 and a second connecting electrode 42 provided on the first surface of the base substrate 10, and a protection layer 11 provided on a side of the first connecting electrode 41 and the second connecting electrode 42 away from the base substrate. The first connecting electrode 41 is connected to the first conductive column 31, the second connecting electrode 42 is connected to the second conductive column 32, and a material of the protection layer 11 includes an organic material.

In an exemplary implementation, the second structure layer 200 may at least include a third connecting electrode 43, a fourth connecting electrode 44, a fifth connecting electrode 45, and a capacitor structure provided on the second surface of the base substrate 10. The fourth connecting electrode 44 is connected to the first conductive column 31, and the fifth connecting electrode 45 is connected to the second conductive column 32. The capacitor structure may include a first plate 51 provided on the second surface of the base substrate 10, a surface insulating layer 12 provided on a side of the first plate 51 away from the base substrate, and a second plate 52 provided on a side of the surface insulating layer 12 away from the base substrate.

In an exemplary implementation, the first connecting electrode 41, the second connecting electrode 42, the third connecting electrode 43, the fourth connecting electrode 44, and the fifth connecting electrode 45 are configured as coil traces of a filter inductor, constituting a filter inductor having a three-dimensional spiral inductance structure. The first plate 51 may serve as a lower plate of the capacitor structure, and the second plate 52 may serve as an upper plate of the capacitor structure, and the first plate 51, the surface insulating layer 12, and the second plate 52 constitute a filter capacitor of a MIM structure.

In an exemplary implementation, the third connecting electrode 43, the fourth connecting electrode 44, the fifth connecting electrode 45, and the first plate 51 may be provided in a same layer and synchronously formed by a same patterning process.

In an exemplary implementation, the filter may further include a first insulating layer 61 provided on a side of the second structure layer 200 away from the base substrate, a lead layer provided on a side of the first insulating layer 61 away from the base substrate, a second insulating layer 62 provided on a side of the lead layer away from the base substrate, and a pad layer provided on a side of the second insulating layer 62 away from the base substrate.

In an exemplary implementation, the first insulating layer 61 may be provided with a first via, a second via, and a third via, and the lead layer may at least include a first lead 71, a second lead 72, and a third lead 73. The first lead 71 is connected to the third connecting electrode 43 through the first via, the second lead 72 is connected to the first plate 51 through the second via, and the third lead 73 is connected to the second plate 52 through the third via. The second insulating layer 62 may be provided with a fourth via, a fifth via, and a sixth via, and the pad layer may at least include a first pad 81, a second pad 82 and a third pad 83. The first pad 81 is connected to the first lead 71 through the fourth via, the second pad 82 is connected to the second lead 72 through the fifth via, and the third pad 83 is connected to the third lead 73 through the sixth via.

In an exemplary implementation, materials of the first insulating layer 61 and the second insulating layer 62 include an organic material, and a thickness of the first insulating layer 61 and a thickness of the second insulating layer 62 may be about 1 μm to 10 μm.

In an exemplary implementation, the first connecting electrode 41 and the second connecting electrode 42 may include a seed layer and a conductive layer that are stacked. The seed layer is provided on the first surface of the base substrate, and the conductive layer is provided on a side of the seed layer away from the base substrate. The third connecting electrode 43, the fourth connecting electrode 44, the fifth connecting electrode 45, and the first plate 51 may each include a seed layer and a conductive layer that are stacked. The seed layer is provided on the second surface of the base substrate, and the conductive layer is provided on a side of the seed layer away from the base substrate.

In an exemplary implementation, the seed layer includes a two-layer structure of a titanium layer and a copper layer, and a thickness of the titanium layer is 10 nm to 200 nm.

In an exemplary implementation, the second plate 52 may adopt a sandwich stacked structure of Ti/Cu/Ti, or a sandwich stacked structure of Ti/Al/Ti.

Exemplary description is made below through a preparation process of a filter. A “patterning process” mentioned in the present disclosure includes film layer deposition, photoresist coating on a film layer, mask exposure, development, etching, photoresist stripping, and other treatments for a metal material, an inorganic material, or a transparent conductive material, and the patterning process includes organic material coating, mask exposure, development, and other treatments for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” needs to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of the film layer is a size of the film layer in a direction perpendicular to the filter. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary implementation, a preparation process of the filter according to the present embodiment may include the following steps.

(11) Forming a metallized TGV base substrate. In an exemplary implementation, forming a metallized TGV base substrate may include the following operations.

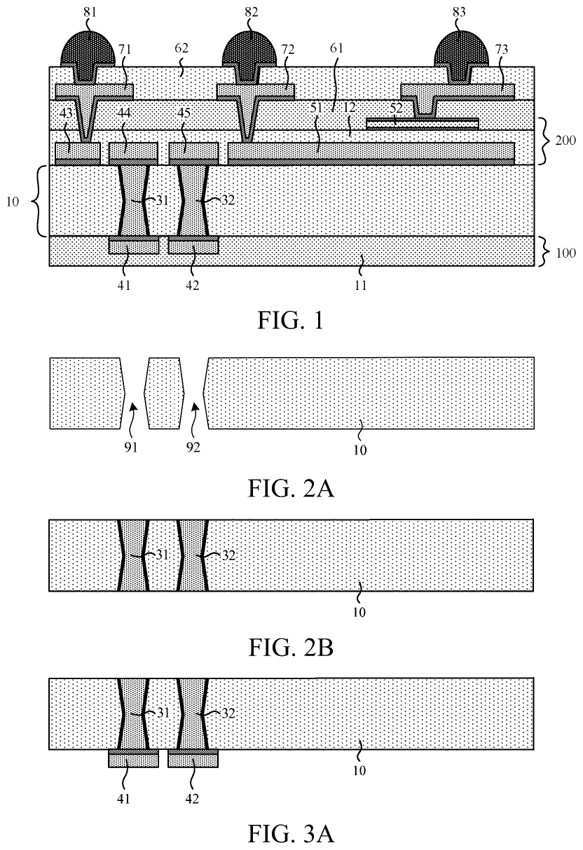

(a1) Providing a base substrate 10, and forming a plurality of through-holes on the base substrate by a process such as laser-induced etching, sandblasting, laser ablation, and the like. The plurality of through-holes may at least include a first through-hole 91 and a second through-hole 92, as shown in FIG. 2A.

In an exemplary implementation, structures of the two through-holes may be substantially the same and both are through-hole structures that penetrate through the base substrate 10. A shape of the through-holes may be circular or elliptical in a plane parallel to the base substrate, a cross-sectional shape of the through-holes may be an hourglass shape in a plane perpendicular to the base substrate, and the through-holes are configured to accommodate conductive columns formed subsequently.

In an exemplary implementation, the base substrate 10 may include a first surface and a second surface opposite to each other, and in the following description, a surface on a lower side of the base substrate 10 is the first surface, and a surface on an upper side of the base substrate 10 is the second surface.

In an exemplary implementation, a material of the base substrate may be alkali-free glass, quartz glass, or the like, and a thickness of the base substrate may be about 0.2 mm to 0.3 mm. For example, the thickness of the base substrate may be about 0.25 mm.

In an exemplary implementation, each through-hole may have a diameter of about 1 μm to 50 μm.

(a2) First, respectively forming a continuous through-hole adhesion layer and a through-hole seed layer on inner side walls of the plurality of through-holes by a deep-hole Physical Vapor Deposition (PVD) process, and then respectively forming a plurality of conductive columns in the plurality of through-holes by a double-sided electroplating process, wherein the plurality of conductive columns may at least include a first conductive column 31 filling the first through-hole 91 and a second conductive column 32 filling the second through-hole 92, and finally removing the conductive material on the second surface and the first surface of the base substrate 10 by a Chemical Mechanical Polishing (CMP) process, as shown in FIG. 2B.

In an exemplary implementation, the structures of the two conductive columns may be substantially the same, and both are filling structures penetrating through the base substrate 10. The shape of the conductive columns may be circular or elliptical in a plane parallel to the base substrate, the cross-sectional shape of the conductive columns may be an hourglass shape in a plane perpendicular to the base substrate, and the through-holes are configured to accommodate conductive columns formed subsequently.

In an exemplary implementation, a material of the through-hole adhesion layer may be titanium (Ti), tantalum (Ta), titanium nitride (TiN), or tantalum nitride (TaN), or other metal or metal nitride having high adhesion to glass, and a thickness of the through-hole adhesion layer may be about 30 nm to 100 nm.

In an exemplary implementation, a material of the through-hole seed layer may adopt copper (Cu), a material of each conductive column may adopt copper (Cu), and a thickness of the through-hole seed layer may be about 30 nm to 100 nm.

(12) Forming a first structure layer. In an exemplary implementation, forming a first structure layer may include the following operations.

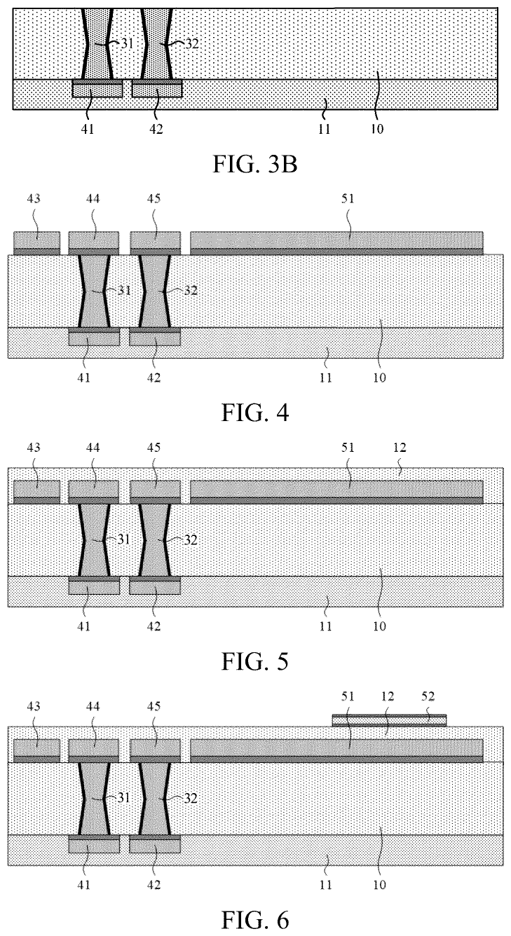

(b1) First, depositing a seed thin film on the first surface of the base substrate 10 by a PVD process, and then forming a conductive layer on the seed thin film by an entire surface electroplating process. Subsequently, a first conductive layer is formed on the first surface of the base substrate 10 by a patterning process of photoresist coating, exposure, development, etching, and striping. The first conductive layer may at least include a first connecting electrode 41 and a second connecting electrode 42 as coil traces of a filter inductor, the first connecting electrode 41 is connected to the first conductive column 31, and the second connecting electrode 42 is connected to the second conductive column 32, as shown in FIG. 3A.

In an exemplary implementation, the seed layer may adopt a two-layer structure of Ti/Cu, a material of the conductive layer may adopt Cu. The Ti layer is in contact with the base substrate, the Cu layer is in contact with the conductive layer, and the Ti layer may effectively enhance the adhesion between Cu and the base substrate.

In an exemplary implementation, the thickness of the titanium layer may be about 10 nm to 200 nm, that is, a distance between the Cu layer in the first connecting electrode 41 and the second connecting electrode 42 and the Cu layer in the base substrate may be about 10 nm to 200 nm. For example, the thickness of the titanium layer may be about 100 nm to 150 nm. As another example, the thickness of the titanium layer may be about 133 nm.

In an exemplary implementation, the thickness of the seed layer may be about 30 nm to 200 nm, and the thickness of the conductive layer may be greater than 1 μm.

(b2) Forming a protection layer. A first protective thin film is spin-coated on the first surface of the base substrate 10 by a spin-coating process to form a protection layer 11 covering the first conductive layer, as shown in FIG. 3B.

In an exemplary implementation, a material of the protection layer 11 may be an insulating material such as polyimide (PI) or a photoresist, and a thickness of the protection layer 11 may be about 1 μm to 10 μm.

In an exemplary implementation, the material of the protection layer 11 may have a dielectric constant of about 3, and a dielectric loss of about 0.001, which can effectively protect the first connecting electrode 41 and prevent oxidation of the connecting electrode.

In an exemplary implementation, the first conductive layer provided on the first surface of the base substrate and the protection layer 11 provided on a side of the first conductive layer away from the base substrate constitute the first structure layer.

(13) Forming a second structure layer. In an exemplary implementation, forming a second structure layer may include: first, depositing a seed thin film on the second surface of the base substrate 10 by a PVD process, and then forming a conductive layer on the seed thin film by a subtractive entire surface electroplating process. Subsequently, a second conductive layer is formed on the second surface of the base substrate 10 by a patterning process of photoresist coating, exposure, development, wet etching, and striping. The second conductive layer may at least include a first plate 51 and a third connecting electrode 43, a fourth connecting electrode 44, and a fifth connecting electrode 45, which are coil traces of a filter inductor. The fourth connecting electrode 44 is connected to the first conductive column 31, and the fifth connecting electrode 45 is connected to the second conductive column 32, as shown in FIG. 4.

In an exemplary implementation, the seed layer may adopt a two-layer structure of Ti/Cu, and the material of the conductive layer may adopt Cu. The Ti layer is in contact with the base substrate, the Cu layer is in contact with the conductive layer, and the Ti layer may effectively enhance the adhesion between Cu and the base substrate.

In an exemplary implementation, the thickness of the titanium layer may be about 10 nm to 200 nm, that is, a distance between the Cu layer in the third connecting electrode 43, the fourth connecting electrode 44, and the fifth connecting electrode 45 and the Cu layer in the base substrate may be about 10 nm to 200 nm.

In an exemplary implementation, the thickness of the seed layer may be about 30 nm to 200 nm, and the thickness of the conductive layer may be greater than 1 μm.

In an exemplary implementation, the third connecting electrode 43, the fourth connecting electrode 44, the first conductive column 31, the first connecting electrode 41, the second connecting electrode 42, the second conductive column 32, and the fifth connecting electrode 45 may be sequentially connected to constitute a filter inductor having a three-dimensional spiral inductance structure.

In an exemplary implementation, the first plate 51 may serve as a lower plate of the capacitor structure, and the first plate 51 may include a seed layer (Ti/Cu) and a conductive layer (Cu) that are stacked.

(14) Forming a surface insulating layer. In an exemplary implementation, forming a surface insulating layer may include: depositing and forming a surface insulating layer 12 on the second surface of the base substrate 10 by a process such as Chemical Vapor Deposition (CVD), Plasma Enhanced Chemical Vapor Deposition (PECVD), Low Pressure Chemical Vapor Deposition (LPCVD), or Atomic Layer Deposition (ALD), and the like. The surface insulating layer 12 covers the third connecting electrode 43, the fourth connecting electrode 44, the fifth connecting electrode 45 and the first plate 51. The surface insulating layer 12 covering the third connecting electrode 43, the fourth connecting electrode 44 and the fifth connecting electrode 45 serves as an insulating protection layer, and the surface insulating layer 12 covering the first electrode 51 serves as a capacitor dielectric layer of the capacitor structure, as shown in FIG. 5.

In an exemplary implementation, a material such as silicon nitride (SiNx), silicon oxide (SiO₂), or aluminum oxide (AL₂O₃) may be used as the material of the surface insulating layer 12, and the thickness of the surface insulating layer 12 (as a capacitor dielectric layer) covering a region of the first plate 51 may be 100 nm to 200 nm.

(15) Forming a second plate. In an exemplary implementation, forming a second plate may include: depositing a second plate conductive thin film, and patterning the second plate conductive thin film by a patterning process to form the second plate 52 on the capacitor dielectric layer 53, as shown in FIG. 6.

In an exemplary implementation, the second plate 52 may serve as an upper plate of the capacitor structure, and the first plate 51, the capacitor dielectric layer 53, and the second plate 52 constitute a filter capacitor of a MIM structure.

In an exemplary implementation, the second plate 52 may adopt a sandwich stacked structure of a titanium layer/copper layer/titanium layer (Ti/Cu/Ti), or a sandwich stacked structure of a titanium layer/aluminum layer/titanium layer (Ti/Al/Ti). The thickness of the Ti layer may be about 30 nm to 50 nm, and the thickness of the Cu layer or the Al layer may be about 200 nm to 400 nm.

In an exemplary implementation, the second conductive layer provided on the second surface of the base substrate, the surface insulating layer provided on a side of the second conductive layer away from the base substrate, and the second plate provided on a side of the surface insulating layer away from the base substrate constitute the second structure layer.

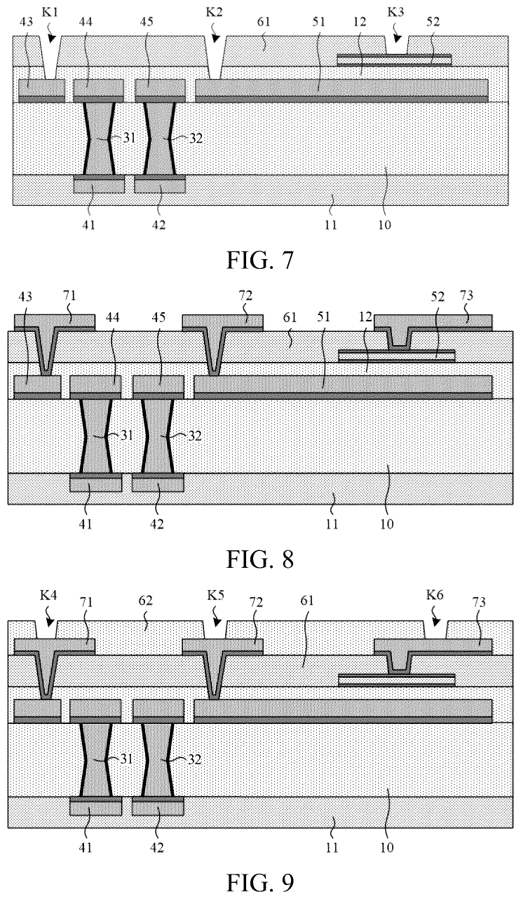

(16) Forming a first insulating layer. In an exemplary implementation, forming a first insulating layer may include: spin-coating a first insulating thin film on the second surface of the base substrate 10 by a spin-coating process, and patterning the first insulating thin film by a patterning process to form a first insulating layer 61 covering the third connecting electrode 43, the fourth connecting electrode 44, the fifth connecting electrode 45, and the capacitor structure. The first insulating layer 61 is provided with a plurality of vias, as shown in FIG. 7.

In an exemplary implementation, the plurality of vias may at least include a first via K1, a second via K2, and a third via K3. An orthographic projection of the first via K1 on the base substrate may be within a range of an orthographic projection of the third connecting electrode 43 on the base substrate, and the first insulating thin film and the surface insulating layer 12 in the first via K1 are removed to expose a surface of the third connecting electrode 43. An orthographic projection of the second via K2 on the base substrate may be within a range of an orthographic projection of the first plate 51 on the base substrate, and the first insulating thin film and the surface insulating layer 12 in the second via K2 are removed to expose a surface of the first plate 51. An orthographic projection of the third via K3 on the base substrate may be within a range of an orthographic projection of the second plate 52 on the base substrate, and the first insulating thin film in the third via K3 is removed to expose a surface of the second plate 52.

In an exemplary implementation, a material of the first insulating layer 61 may be an insulating material such as polyimide, and a thickness of the first insulating layer 61 may be about 1 μm to 10 μm.

(17) Forming a lead layer. In an exemplary implementation, forming a lead layer may include: first, sequentially depositing a lead adhesion thin film and a lead seed thin film on the first insulating layer 61 by a PVD process, and patterning the lead adhesion thin film and the lead seed thin film by a patterning process. Subsequently, a lead material is electroplated on the lead seed thin film by an additive electroplating process, and a lead layer is formed on the first insulating layer 61 by a wet etching process. The lead layer may at least include a first lead 71 connected to the third connecting electrode 43 through the first via K1, a second lead 72 connected to the first plate 51 through the second via K2, and a third lead 73 connected to the second plate 52 through the third via K3, as shown in FIG. 8.

In an exemplary implementation, a material of the lead adhesion layer may adopt Ti, a material of the lead seed layer may adopt Cu, and a material of the lead material may adopt Cu.

In an exemplary implementation, a thickness of the first lead 71, the second lead 72, and the third lead 73 may be about 1 μm to 10 μm.

(18) Forming a second insulating layer. In an exemplary implementation, forming a second insulating layer may include: spin-coating a second insulating thin film on the second surface of the base substrate 10 by a spin-coating process, and patterning the second insulating thin film by a patterning process to form a second insulating layer 62 covering the first lead 71, the second lead 72, and the third lead 73. The second insulating layer 62 is provided with a plurality of vias, as shown in FIG. 9.

In an exemplary implementation, the plurality of vias may at least include a fourth via K4, a fifth via K5, and a sixth via K6. An orthographic projection of the fourth via K4 on the base substrate may be within a range of an orthographic projection of the first lead 71 on the base substrate, and the second insulating thin film in the fourth via K4 is removed to expose a surface of the first lead 71. An orthographic projection of the fifth via K5 on the base substrate may be within a range of an orthographic projection of the second lead 72 on the base substrate, and the second insulating thin film in the fifth via K5 is removed to expose a surface of the second lead 72. An orthographic projection of the sixth via K6 on the base substrate may be within a range of an orthographic projection of the third lead 73 on the base substrate, and the second insulating thin film in the sixth via K6 is removed to expose a surface of the third lead 73.

In an exemplary implementation, a material of the second insulating layer 62 may be an insulating material such as polyimide, and a thickness of the second insulating layer 62 may be about 1 μm to 10 μm.

(19) Forming a pad layer. In an exemplary implementation, forming a pad layer may include: first, sequentially depositing a pad adhesion thin film and a pad seed thin film on the second insulating layer 62 by a PVD process, and patterning the pad adhesion thin film and the pad seed thin film by a patterning process. Subsequently, a pad material is electroplated on the pad seed thin film by an electroplating process, and a pad layer is formed on the second insulating layer 62 by an etching and reflow process. The pad layer may at least include a first pad 81 connected to the first lead 71 through the fourth via K4, a second pad 82 connected to the second lead 72 through the fifth via K5, and a third pad 83 connected to the third lead 73 through the sixth via K6, as shown in FIG. 1.

In an exemplary implementation, cross-sectional shapes of the first pad 81, the second pad 82, and the third pad 83 may be circular, elliptical, rectangular, polygonal, or the like in the plane parallel to the base substrate, and cross-sectional shapes of the first pad 81, the second pad 82, and the third pad 83 may be semi-circular, semi-elliptical, or trapezoidal, or the like in the plane perpendicular to the base substrate. The first pad 81, the second pad 82, and the third pad 83 may be referred to as bumps.

In an exemplary implementation, a material of the pad adhesion thin film may adopt Ti, a material of the pad seed thin film may adopt Cu, and the pad layer may adopt a stacked structure of Cu/Ni/SnAg, or a stacked structure of Cu/Ni/Sn. The thickness of the Ni layer may be about 30 nm to 100 nm, the thickness of the Cu layer may be about 200 nm to 600 nm, and the thickness of the tin-silver alloy (SnAg) layer or the tin (Sn) layer may be about 200 nm to 500 nm, which not only has good stretchability but also has anti-corrosion properties. In the present disclosure, by providing a Ni layer as a barrier layer, it is possible to effectively prevent Sn from permeating into Cu.

Thus, the preparation of the filter of the present embodiment is completed. In an exemplary implementation, the filter of the present embodiment may include a base substrate, a first structure layer provided on the first surface of the base substrate, and a second structure layer provided on the second surface of the base substrate. The first structure layer may include a first connecting electrode and a second connecting electrode provided on the first surface of the base substrate, and a protection layer covering the first connecting electrode and the second connecting electrode. The second structure layer may include a third connecting electrode, a fourth connecting electrode, a fifth connecting electrode, and a capacitor structure provided on the second surface of the base substrate. The filter further includes: a first insulating layer covering the third connecting electrode, the fourth connecting electrode, the fifth connecting electrode and the capacitor structure; a first lead, a second lead, and a third lead provided on the first insulating layer; a second insulating layer covering the first lead, the second lead, and the third lead; and a first pad, a second pad, and a third pad provided on the second insulating layer.

In a filter, the first insulating layer and the second insulating layer adopt an inorganic material. Due to the thin thickness of the first insulating layer and the second insulating layer, which is less than 300 nm, on the one hand, it will lead to the formation of large parasitic capacitance between the conductive layers, thus seriously affecting the performance of the filter, on the other hand, it will lead to poor drilling and etching, resulting in unstable device performance. Due to the thin thickness of the first insulating layer and the second insulating layer, the coverage of edge positions of the connecting electrodes is not ideal, and even cracks may occur. In the subsequent wet etching process, the etching solution will etch the connecting electrode at the crack, resulting in poor drilling and etching. The first insulating layer and the second insulating layer of the filter of the present disclosure adopt thick organic materials, which can not only effectively reduce the parasitic capacitance between the conductive layers, but also effectively avoid poor drilling and etching, thus ensuring the performance stability and reliability of the filter, and improving the performance of the filter.

The filter of the present disclosure adopts a glass base substrate, which can not only reduce filter loss, but also reduce production cost. The filter of the present disclosure realizes the glass magnetic core TGV 3D spiral inductor through the TGV technology, which effectively improves the inductance value and the Q value per unit area, makes the filter structure more compact, reduces the filter size, and makes the filter easier to integrate.

The filter of the present disclosure adopts a seed layer including a titanium layer and a copper layer. The titanium layer is in contact with the base substrate and the thickness of the titanium layer is 10 nm to 200 nm, which can not only effectively enhance the adhesion between the connecting electrode and the base substrate, but also ensure the seamless lapping between the connecting electrode and the conductive column.

The preparation process according to the present disclosure may be implemented using an existing mature preparation equipment, with minimal improvement to the existing process. The preparation process may be well compatible with an existing preparation process, be simple to implement, and be easy to practice, thereby achieving high production efficiency, low production cost and high yield rate.

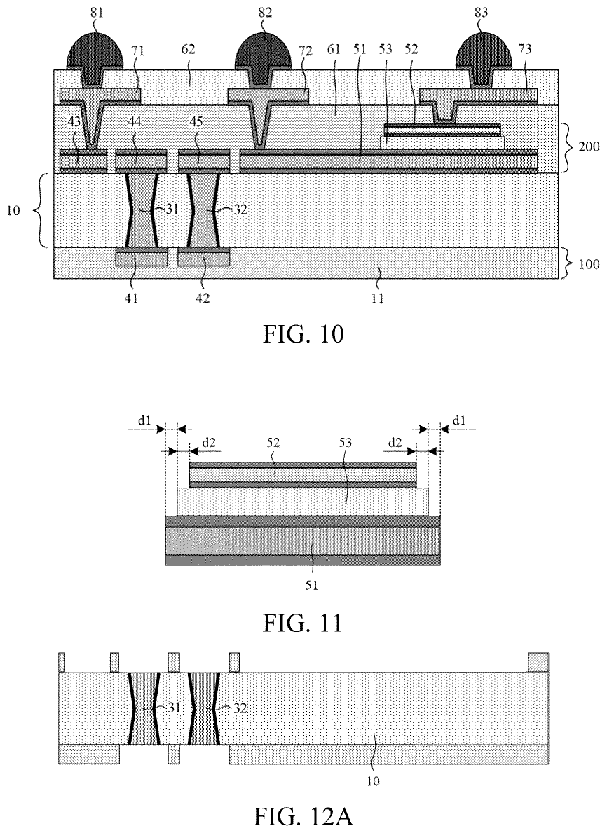

FIG. 10 is a schematic diagram of a structure of another filter according to an exemplary embodiment of the present disclosure. As shown in FIG. 10, a main body structure of the filter of the exemplary embodiment according to the present disclosure may include a base substrate 10, a first structure layer 100 provided on a first surface of the base substrate 10, and a second structure layer 200 provided on a second surface of the base substrate 10. Main body structures of the base substrate 10 and the first structure layer 100 of the present embodiment are substantially the same as those of the foregoing embodiment.

In an exemplary implementation, the second structure layer 200 may at least include a third connecting electrode 43, a fourth connecting electrode 44, a fifth connecting electrode 45, and a capacitor structure provided on a second surface of the base substrate 10. The fourth connecting electrode 44 is connected to the first conductive column 31, and the fifth connecting electrode 45 is connected to the second conductive column 32. The capacitor structure may include a first plate 51 provided on the second surface of the base substrate 10, a capacitor dielectric layer 53 provided on a side of the first plate 51 away from the base substrate, and a second plate 52 provided on a side of the capacitor dielectric layer 53 away from the base substrate.

In an exemplary implementation, the first connecting electrode 41, the second connecting electrode 42, the third connecting electrode 43, the fourth connecting electrode 44, and the fifth connecting electrode 45 are configured as coil traces of a filter inductor, constituting a filter inductor having a three-dimensional spiral inductance structure. The first plate 51 may serve as a lower plate of the capacitor structure, and the second plate 52 may serve as an upper plate of the capacitor structure, and the first plate 51, the capacitor dielectric layer 53, and the second plate 52 constitute a filter capacitor of a MIM structure.

In an exemplary implementation, the third connecting electrode 43, the fourth connecting electrode 44, the fifth connecting electrode 45, and the first plate 51 may be provided in a same layer and synchronously formed by a same Damascene process.

In an exemplary implementation, the filter may further include a first insulating layer 61 provided on a side of the second structure layer 200 away from the base substrate, a lead layer provided on a side of the first insulating layer 61 away from the base substrate, a second insulating layer 62 provided on a side of the lead layer away from the base substrate, and a pad layer provided on a side of the second insulating layer 62 away from the base substrate. Main body structures of the first insulating layer 61, the lead layer, the second insulating layer 62, and the pad layer are substantially the same as those of the foregoing embodiment.

In an exemplary implementation, the first connecting electrode 41 and the second connecting electrode 42 may include a seed layer and a conductive layer that are stacked. The seed layer is provided on a first surface of the base substrate, and the conductive layer is provided on a side of the seed layer away from the base substrate. A thickness of the conductive layer may be greater than 1 μm.

In an exemplary implementation, the third connecting electrode 43, the fourth connecting electrode 44, the fifth connecting electrode 45, and the first plate 51 may each include a seed layer, a conductive layer and a conductive protection layer that are stacked. The seed layer is provided on the second surface of the base substrate, the conductive layer is provided on a side of the seed layer away from the base substrate, and the conductive protection layer is provided on a side of the conductive layer away from the base substrate. The conductive protection layer is configured to prevent diffusion of the conductive layer to the capacitor dielectric layer and increase adhesion between the conductive layer and the capacitor dielectric layer.

In an exemplary implementation, the seed layer includes a two-layer structure of a titanium layer and a copper layer, the thickness of the titanium layer is 10 nm to 200 nm, and the material of the conductive protection layer includes titanium.

In an exemplary implementation, the second plate 52 may adopt a sandwich stacked structure of Ti/Cu/Ti, or a sandwich stacked structure of Ti/Al/Ti.

FIG. 11 is a schematic cross-sectional structural view of a capacitor structure according to an exemplary embodiment of the present disclosure. As shown in FIG. 11, both the capacitor dielectric layer 53 and the second plate 52 are patterned by a dry etching process, and an orthographic projection of the second plate 52 on the base substrate may be within a range of an orthographic projection of the capacitor dielectric layer 53 on the base substrate, and the orthographic projection of the capacitor dielectric layer 53 on the base substrate may be within a range of an orthographic projection of the first plate 51 on the base substrate.

In an exemplary implementation, areas of the first plate 51, the capacitor dielectric layer 53, and the second plate 52 sequentially decrease along a direction away from the base substrate.

In an exemplary implementation, in a plane parallel to the base substrate, there is a first distance d1 between an edge of the first plate 51 and an edge of the capacitor dielectric layer 53 in at least one direction, and the first distance d1 may be greater than or equal to 50 nm.

In an exemplary implementation, in a plane parallel to the base substrate, there is a second distance d2 between the edge of the capacitor dielectric layer 53 and an edge of the second plate 52 in at least one direction, and the second distance d2 may be greater than or equal to 50 nm.

In an exemplary implementation, the preparation process of the filter of the present embodiment may include the following steps.

(21) Forming a metallized TGV base substrate. The preparation process and the formed structure are substantially the same as those of step (11) of the foregoing embodiment.

(22) Forming a first structure layer and a second conductive layer. In an exemplary implementation, forming a first structure layer and a second conductive layer may include the following operations.

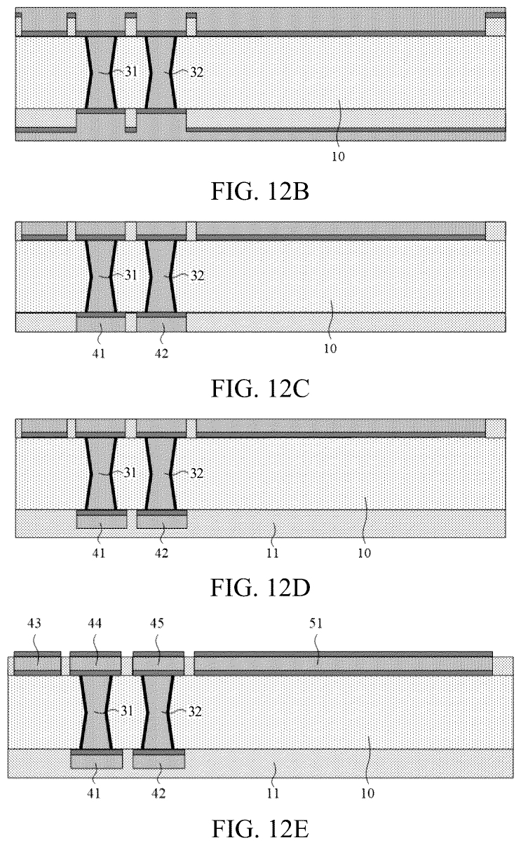

(b1) Spin-coating a first photoresist layer on the first surface of the base substrate 10 and a second photoresist layer on the second surface of the base substrate 10 by a spin-coating process. A first trace pattern is formed on the first photoresist layer and a second trace pattern is formed on the second photoresist layer by a patterning process involving exposure and development. The first photoresist layer at a position where the first trace pattern is located is removed to expose the first surface of the base substrate 10, and the second photoresist layer at a position where the second trace pattern is located is removed to expose the second surface of the base substrate 10, as shown in FIG. 12A.

In an exemplary implementation, materials of the first photoresist layer and the second photoresist layer may adopt polyimide, and a thickness of the first photoresist layer and a thickness of the second photoresist layer may be about 1 μm to 10 μm.

(b2) First, depositing seed thin films on the first surface and the second surface of the base substrate 10 by a PVD process. The seed thin film at a position where the first trace pattern is located is provided on the first surface of the base substrate 10, and the seed thin film at a region except the first trace pattern is provided on the first photoresist layer. The seed thin film at a position where the second trace pattern is located is provided on the second surface of the base substrate 10, and the seed thin film at a region except the second trace pattern is provided on the second photoresist layer. Subsequently, conductive layers are formed on the seed thin films on the first surface and the second surface of the base substrate 10 by an additive electroplating process, and the conductive layer is higher than the photoresist layer. On the first surface of the base substrate 10, a distance between a surface of the conductive layer away from the base substrate and the first surface is greater than a distance between a surface of the first photoresist layer away from the base substrate and the first surface. On the second surface of the base substrate 10, a distance between a surface of the conductive layer away from the base substrate and the second surface is greater than a distance between a surface of the second photoresist layer away from the base substrate and the second surface, as shown in FIG. 12B.

In an exemplary implementation, the seed layer may adopt a two-layer structure of Ti/Cu, the material of the conductive layer may adopt Cu, and the Ti layer is in contact with the base substrate The thickness of the titanium layer is 10 nm to 200 nm, the Cu layer is in contact with the conductive layer, and the Ti layer can effectively enhance the adhesion between Cu and the base substrate.

In an exemplary implementation, the thickness of the seed layer may be about 30 nm to 200 nm.

(b3) Respectively removing the conductive layers and the seed thin films on the first photoresist layer and the second photoresist layer by a CMP process and using the first photoresist layer and the second photoresist layer as cut-off layers, to form a first conductive layer on the first surface of the base substrate 10 and to form a transition conductive layer on the second surface of the base substrate 10. The first conductive layer may at least include a first connecting electrode 41 connected to the first conductive column 31 and a second connecting electrode 42 connected to the second conductive column 32, as shown in FIG. 12C.

In an exemplary implementation, the first connecting electrode 41 and the second connecting electrode 42 may include a seed layer (Ti/Cu) and a conductive layer (Cu) that are stacked, and the thickness of the conductive layer may be greater than 1 μm.

(b4) Forming a protection layer. A first protective thin film is spin-coated on the first surface of the base substrate 10 by a spin-coating process to form a protection layer 11 covering the first conductive layer, as shown in FIG. 12D.

In an exemplary implementation, the material of the protection layer 11 may be an insulating material such as polyimide (PI) or a photoresist, and the thickness of the protection layer 11 may be about 1 μm to 10 μm.

In an exemplary implementation, the material of the protection layer 11 may have a dielectric constant of about 3, and a dielectric loss of about 0.001, which can effectively protect the first connecting electrode 41 and prevent oxidation of the connecting electrode.

In an exemplary implementation, the first conductive layer provided on the first surface of the base substrate and the protection layer 11 provided on a side of the first conductive layer away from the base substrate constitute the first structure layer.

(b5) Forming a second conductive layer. A protective conductive thin film is deposited on the second surface of the base substrate 10 by a PVD process, and the protective conductive thin film is patterned by a patterning process to form a conductive protection layer on the transition conductive layer, and the conductive protection layer and the transition conductive layer together constitute a second conductive layer. The second conductive layer may at least include a third connecting electrode 43, a fourth connecting electrode 44, a fifth connecting electrode 45, and a first plate 51. The fourth connecting electrode 44 is connected to the first conductive column 31, and the fifth connecting electrode 45 is connected to the second conductive column 32, as shown in FIG. 12E.

In an exemplary implementation, the material of the conductive protection layer may adopt Ti, and the thickness of the conductive protection layer may be about 30 nm to 100 nm. In an exemplary implementation, the conductive protection layer may, on the one hand, prevent the conductive layer (Cu) from diffusing to a capacitor dielectric layer formed subsequently, and on the other hand, increase adhesion between the conductive layer (Cu) and the capacitor dielectric layer formed subsequently.

In an exemplary implementation, the third connecting electrode 43, the fourth connecting electrode 44, and the fifth connecting electrode 45 are configured as coil traces of a filter inductor, and may each include a seed layer (Ti/Cu), a conductive layer (Cu), and a conductive protection layer (Ti) that are stacked. The thickness of the conductive layer may be greater than 1 μm.

In an exemplary implementation, the first plate 51 may serve as a lower plate of the capacitor structure, the first plate 51 may include a seed layer (Ti/Cu), a conductive layer (Cu), and a conductive protection layer (Ti) that are stacked, and the thickness of the conductive layer may be greater than 1 μm.

In an exemplary implementation, the first plate 51 may be directly connected to the fifth connecting electrode 45, or may be connected to the fifth connecting electrode 45 through a connecting electrode.

In an exemplary implementation, since the transition conductive layer in the second conductive layer is formed by the CMP process, the first plate 51 formed by the present disclosure has good thickness uniformity, surface flatness, and surface smoothness, which is beneficial to improve the uniformity of the capacitor dielectric layer formed subsequently, and is beneficial to improve the uniformity of the capacitor structure.

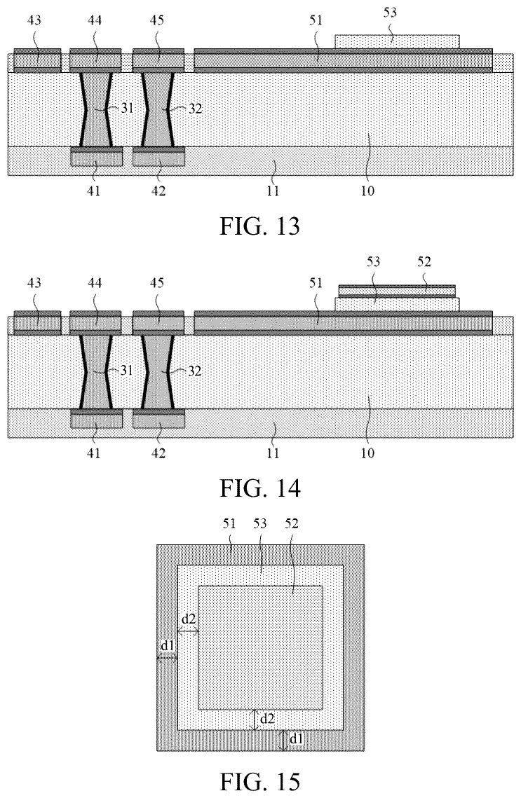

(23) Forming a capacitor dielectric layer. In an exemplary implementation, forming a capacitor dielectric layer may include: depositing a capacitive dielectric thin film on the second surface of the base substrate 10 by a process such as CVD, PECVD, LPCVD, or ALD, and patterning the capacitive dielectric thin film by a patterning process to form a capacitor dielectric layer 53 on the first plate 51, as shown in FIG. 13.

In an exemplary implementation, forming the capacitor dielectric layer 53 may adopt a dry etching process for patterning, and an orthographic projection of the capacitor dielectric layer 53 on the base substrate may be within a range of an orthographic projection of the first plate 51 on the base substrate.

In an exemplary implementation, the material of the capacitor dielectric layer 53 may adopt a material such as silicon nitride (SiNx), silicon oxide (SiO₂), or aluminum oxide (AL₂O₃), and the thickness of the capacitor dielectric layer 53 may be 100 nm to 200 nm. Since the first plate 51 has good thickness uniformity and surface smoothness, the capacitor dielectric layer of the present disclosure has good thickness uniformity, and the capacitance uniformity of the capacitor structure is effectively improved.

(24) Forming a second plate. In an exemplary implementation, forming a second plate may include: depositing a second plate conductive thin film on the second surface of the base substrate 10 by a PVD process, and patterning the second plate conductive thin film by a patterning process to form the second plate 52 on the capacitor dielectric layer 53, as shown in FIG. 14.

In an exemplary implementation, the second plate 52 may be patterned by a dry etching process, and an orthographic projection of the second plate 52 on the base substrate may be within a range of the orthographic projection of the capacitor dielectric layer 53 on the base substrate.

In an exemplary implementation, the second plate 52 may serve as an upper plate of the capacitor structure, and the first plate 51, the capacitor dielectric layer 53, and the second plate 52 constitute a filter capacitor of a MIM structure.

In an exemplary implementation, the second plate 52 may adopt a sandwich stacked structure of Ti/Cu/Ti, or a sandwich stacked structure of Ti/Al/Ti. The thickness of the Ti layer may be about 30 nm to 50 nm, and the thickness of the Cu layer or the Al layer may be about 200 nm to 400 nm.

In an exemplary implementation, the second conductive layer provided on the second surface of the base substrate, the capacitor dielectric layer provided on a side of the second conductive layer away from the base substrate, and the second plate provided on a side of the capacitor dielectric layer away from the base substrate constitute the second structure layer.

FIG. 15 is a schematic diagram of a planar structure of a capacitor structure according to an exemplary embodiment of the present disclosure. As shown in FIG. 15, the capacitor structure of MIM structure may include a first plate 51, a capacitor dielectric layer 53 and a second plate 52. The capacitor dielectric layer 53 is provided on a side of the first plate 51 away from the base substrate, and the second plate 52 is provided on a side of the capacitor dielectric layer 53 away from the base substrate. The shapes of the first plate 51, the capacitor dielectric layer 53 and the second plate 52 are rectangular.

In an exemplary implementation, the areas of the first plate 51, the capacitor dielectric layer 53, and the second plate 52 sequentially decrease along a direction away from the base substrate 10.

In an exemplary implementation, both the capacitor dielectric layer 53 and the second plate 52 are patterned by a dry etching process, and the etching accuracy is high, which not only effectively improves the dimensional accuracy and capacitance uniformity of the capacitor structure, and but also can ensure the dimensional accuracy of the capacitor dielectric layer 53 and the second plate 52. Furthermore, by providing that the areas of the first plate 51, the capacitor dielectric layer 53 and the second plate 52 sequentially decrease, an orthographic projection of the second plate 52 on the base substrate can be located within a range of an orthographic projection of the capacitor dielectric layer 53 on the base substrate, and the orthographic projection of the capacitor dielectric layer 53 on the base substrate can be located within a range of an orthographic projection of the first plate 51 on the base substrate. The dimensional accuracy is further ensured, the effective area of the plates is effectively ensured, and the performance consistency of the device is improved.

In an exemplary implementation, in a plane parallel to the base substrate 10, in at least one direction, there is a first distance d1 between an edge of the first plate 51 and an edge of the capacitor dielectric layer 53, and there is a second distance d2 between the edge of the capacitor dielectric layer 53 and an edge of the second plate 52. The first distance d1 may be greater than or equal to 50 nm, and the second distance d2 may be greater than or equal to 50 nm.

By providing the stacked relationship of the first plate, the capacitor dielectric layer, and the second plate in the present disclosure, the processing accuracy of the capacitor structure is effectively ensured, the effective area of the capacitor structure is effectively ensured, and the performance consistency of the filter is improved.

(25)-(28) Sequentially forming a first insulating layer, a lead layer, a second insulating layer, and a pad layer. The preparation process and the formed structure are substantially the same as those of the steps (15)-(18) of the foregoing embodiment, as shown in FIG. 10.

In a capacitor structure of a filter, the lower plate is made by subtractive electroplating, and the upper plate is formed by wet etching process. Because the surface of the lower plate is not flat and rough, the thickness of the capacitor dielectric layer is uneven, which leads to the problems such as uneven capacitance value of the capacitor structure. Because of the low accuracy of wet etching, the dimensional deviation of the capacitor structure is large, which leads to the problems such as low performance consistency of the filter. In the filter provided by the embodiment of the present disclosure, the first plate of the capacitor structure is prepared by a Damascene process including additive electroplating and CMP, and the first plate has better thickness uniformity, surface flatness and surface smoothness, so that the capacitor dielectric layer has better thickness uniformity, and the capacitance uniformity of the capacitor structure is effectively improved. The capacitor dielectric layer and the second plate of the capacitor structure of the present disclosure are prepared by dry etching process, and the etching accuracy is high, which not only effectively improves the dimensional accuracy and dimensional uniformity of the capacitor structure, but also can effectively guarantee the effective area of the plate by providing that the areas of the first plate, the capacitor dielectric layer and the second plate sequentially decrease. This further improves the processing accuracy of the capacitor structure, ensures the dimensional accuracy and dimensional uniformity, improves the performance consistency of the filter, and improves the product yield and product quality.

By means of the optimized additive electroplating and CMP process in the present disclosure, the seamless lapping of the connecting electrode and the conductive column can be ensured, the process procedure is reduced, and the working reliability and performance stability of the filter are effectively improved.

In a capacitor structure of a filter, a lower plate adopts a stacked structure of Ti/Cu. Since Cu is in direct contact with the capacitor dielectric layer (SiNx), not only Cu ions will diffuse into SiNx, but also the adhesion between the two is small, which is prone to striping, resulting in abnormal filter characteristics or even failure. The first plate of the capacitor structure of the present disclosure adopts a stacked structure of Ti/Cu/Ti, and the Ti layer is in contact with SiNx, which not only blocks diffusion of Cu ions into SiNx, but also avoids stripping, and effectively improves reliability and stability of the filter.

The first insulating layer and the second insulating layer of the capacitor structure according to the embodiment of the present disclosure adopt an organic material and have the thickness of about 1 μm to 10 μm, which can not only effectively reduce parasitic capacitance between the conductive layers, but also effectively avoid poor drilling and etching, ensure performance stability and reliability of the filter, and improve the performance of the filter. The filter of the present disclosure realizes the glass magnetic core TGV 3D spiral inductor through the TGV technology, effectively improves the inductance value and the Q value per unit area, makes the filter structure more compact, reduces the filter size, and makes the filter easier to integrate.

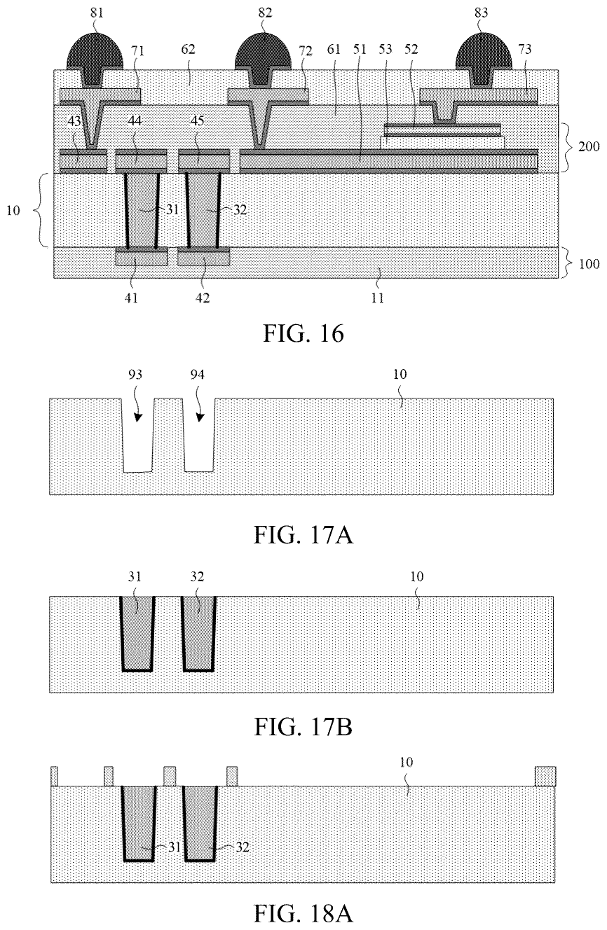

FIG. 16 is a schematic diagram of a structure of yet another filter according to an exemplary embodiment of the present disclosure. The main body structure of the filter of the present embodiment is substantially the same as that of the embodiment shown in FIG. 10, except that the cross-sectional shape of the conductive column embedded in the base substrate of the present embodiment is a column shape or a tapered shape. As shown in FIG. 16, the main body structure of the filter according to the exemplary embodiment of the present disclosure may include a base substrate 10, a first structure layer 100, and a second structure layer 200. The first structure layer 100 may be provided on a first surface of the base substrate 10, and the second structure layer 200 may be provided on a second surface of the base substrate 10. In an exemplary implementation, the structures of the first structure layer 100 and the second structure layer 200 are substantially the same as those of the embodiment shown in FIG. 10, and will not be described in detail here.

In an exemplary implementation, a plurality of conductive columns are embedded in the base substrate 10, the plurality of conductive columns may at least include a first conductive column 31 and a second conductive column 32, and the structures of the two conductive columns may be substantially the same. The shape of the conductive column may be circular or elliptical in a plane parallel to the base substrate, and the cross-sectional shape of the conductive column may be columnar or tapered in a plane perpendicular to the base substrate.

In an exemplary implementation, the base substrate 10 is obtained by first forming a metallized blind via base substrate and then subjecting it to a thinning process.

In an exemplary implementation, the preparation process of the filter of the present embodiment may include the following steps.

(31) Forming a metallized blind via (Blind Via Glass, BGV) base substrate. In an exemplary implementation, forming a metallized BGV base substrate may include the following operations.

(a1) Providing a base substrate 10, and forming a plurality of blind vias on the base substrate by a process such as laser-induced etching, sandblasting, laser ablation, and the like. The plurality of blind vias may at least include a first blind via 93 and a second blind via 94, as shown in FIG. 17A.

In an exemplary implementation, the structure of the two blind vias may be substantially the same, and both of them are blind via structures that do not penetrate through the base substrate 10. The shape of the blind vias may be circular or elliptical in the plane parallel to the base substrate, the cross-sectional shape of the blind vias may be a column shape, a tapered shape, or the like in the plane perpendicular to the base substrate, and the blind vias are configured to accommodate conductive columns formed subsequently.

In an exemplary implementation, the cross-sectional shape of the blind vias may be a tapered shape with a taper of less than or equal to 5°.

In an exemplary implementation, two blind vias may be provided on the second surface of the base substrate 10, and the first surface of the base substrate 10 is not provided with a blind via.

In an exemplary implementation, the material of the base substrate may be alkali-free glass, quartz glass, or the like, and the thickness of the base substrate may be about 0.7 mm to 1.0 mm.

In an exemplary implementation, each blind via may have a diameter of about 1 μm to 50 μm.

(a2) First, respectively forming a continuous blind via adhesion layer and a blind via seed layer on inner side walls of the plurality of blind vias by a PVD process, and then respectively forming a plurality of conductive columns in the plurality of blind vias by a electroplating process. The plurality of conductive columns may at least include a first conductive column 31 filling the first blind via 93 and a second conductive column 32 filling the second blind via 94. Finally, the conductive material on the second surface of the base substrate 10 is removed by a CMP process, as shown in FIG. 17B.

In an exemplary implementation, the materials of the blind via adhesion layer, the blind via seed layer, and the conductive column are substantially the same as those of the foregoing embodiments.

(32) Forming a second conductive layer. In an exemplary implementation, forming a second conductive layer may include the following operations.

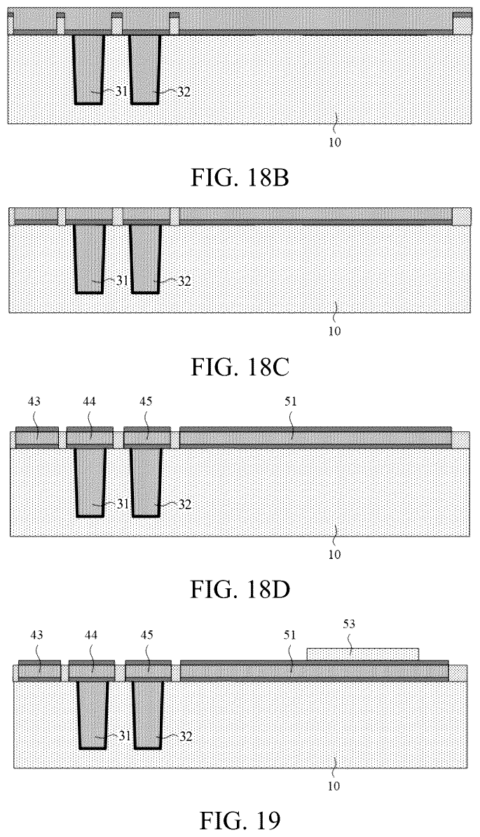

(b1) Spin-coating a photoresist layer on the second surface of the base substrate 10 by a spin-coating process. A trace pattern is formed on the photoresist layer by a patterning process involving exposure and development, and the photoresist layer at a position where the trace pattern is located is removed to expose the second surface of the base substrate 10, as shown in FIG. 18A.

(b2) First, depositing a seed thin film on the second surface of the base substrate 10 by a PVD process. The seed thin film at a position where the trace pattern is located is provided on the second surface of the base substrate 10, and the seed thin film in a region except the trace pattern is provided on the photoresist layer. Subsequently, a conductive layer is formed on the seed thin film on the second surface of the base substrate 10 by an additive electroplating process. The conductive layer is higher than the photoresist layer, that is, a distance between a surface of the conductive layer away from the base substrate and the second surface is greater than a distance between a surface of the photoresist layer away from the base substrate and the second surface, as shown in FIG. 18B.

In an exemplary implementation, the seed layer may adopt a two-layer structure of Ti/Cu, and the material of the conductive layer may adopt Cu. The Ti layer is in contact with the base substrate, the Cu layer is in contact with the conductive layer, and the Ti layer may effectively enhance the adhesion between Cu and the base substrate.

(b3) Completely removing the conductive layer and the seed thin film on the photoresist layer by a CMP process and using the photoresist layer as a cut-off layer, to form a transition conductive layer on the second surface of the base substrate 10, as shown in FIG. 18C.

(b4) Forming a second conductive layer. A protective conductive thin film is deposited on the second surface of the base substrate 10 by a PVD process, and the protective conductive thin film is patterned by a patterning process to form a conductive protection layer on the transition conductive layer, and the conductive protection layer and the transition conductive layer together constitute a second conductive layer. The second conductive layer may at least include a third connecting electrode 43, a fourth connecting electrode 44, a fifth connecting electrode 45, and a first plate 51. The fourth connecting electrode 44 is connected to the first conductive column 31, as shown in FIG. 18D.

In an exemplary implementation, the material of the conductive protection layer may adopt Ti, and the thickness of the conductive protection layer may be about 30 nm to 100 nm. In an exemplary implementation, the conductive protection layer may, on the one hand, prevent the conductive layer (Cu) from diffusing to a capacitor dielectric layer formed subsequently, and on the other hand, increase adhesion between the conductive layer (Cu) and the capacitor dielectric layer formed subsequently.

In an exemplary implementation, the third connecting electrode 43, the fourth connecting electrode 44, and the fifth connecting electrode 45 may each include a seed layer (Ti/Cu), a conductive layer (Cu), and a conductive protection layer (Ti) that are stacked, and the thickness of the conductive layer may be greater than 1 μm.

In an exemplary implementation, the first plate 51 may serve as a lower plate of the capacitor structure, and the first plate 51 may include a seed layer (Ti/Cu), a conductive layer (Cu), and a conductive protection layer (Ti) that are stacked.

In an exemplary implementation, since the transition conductive layer in the second conductive layer is formed by the CMP process, the first plate 51 formed by the present disclosure has good thickness uniformity, surface flatness, and surface smoothness, which is beneficial to improve the uniformity of the capacitor dielectric layer formed subsequently, and is beneficial to improve the uniformity of the capacitor structure.

(33) Forming a capacitor dielectric layer. In an exemplary implementation, the structure and process of forming a capacitor dielectric layer 53 may be substantially the same as those of the embodiment shown in FIG. 10, as shown in FIG. 19.

In an exemplary implementation, since the first plate 51 has good thickness uniformity and surface smoothness, the capacitor dielectric layer of the present disclosure has good thickness uniformity, and the capacitance uniformity of the capacitor structure is effectively improved.

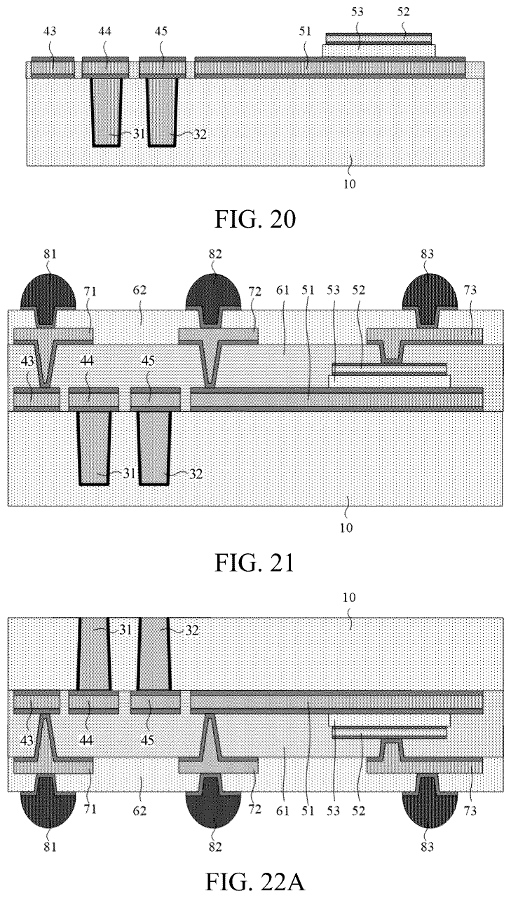

(34) Forming a second plate. In an exemplary implementation, the structure and process of forming a second plate 52 may be substantially the same as the embodiment shown in FIG. 10, as shown in FIG. 20.

In an exemplary implementation, both the capacitor dielectric layer 53 and the second plate 52 are patterned by a dry etching process, and an orthographic projection of the second plate 52 on the base substrate may be within a range of an orthographic projection of the capacitor dielectric layer 53 on the base substrate, and the orthographic projection of the capacitor dielectric layer 53 on the base substrate may be within a range of an orthographic projection of the first plate 51 on the base substrate. The second plate 52 may serve as an upper plate of the capacitor structure, and the first plate 51, the capacitor dielectric layer 53, and the second plate 52 constitute a filter capacitor of a MIM structure.

In an exemplary implementation, the areas of the first plate 51, the capacitor dielectric layer 53, and the second plate 52 sequentially decrease. In at least one direction, there is a first distance between an edge of the first plate 51 and an edge of the capacitor dielectric layer 53, and there is a second distance between the edge of the capacitor dielectric layer 53 and an edge of the second plate 52. The first distance may be greater than or equal to 50 nm, and the second distance may be greater than or equal to 50 nm.

(35)-(38) Sequentially forming a first insulating layer, a lead layer, a second insulating layer, and a pad layer. The preparation process and the formed structure are substantially the same as those of the steps (15)-(18) of the foregoing embodiment, as shown in FIG. 21.

(39) Forming a first structure layer. In an exemplary implementation, forming a first structure layer may include the following operations.

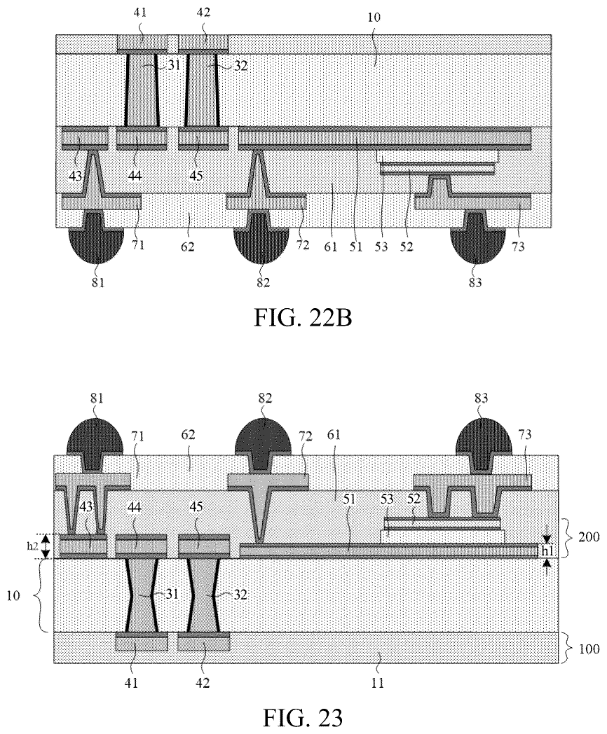

(c1) Flipping the base substrate 10, and thinning the first surface of the base substrate 10 until two conductive columns are exposed on the first surface, as shown in FIG. 22A.

(c2) Spin-coating a photoresist layer on the first surface of the base substrate 10 by a spin-coating process, and forming a trace pattern on the photoresist layer by a patterning process involving exposure and development. The photoresist layer at a position where the trace pattern is located is removed to expose the first surface of the base substrate 10. First, a seed thin film is deposited on the first surface of the base substrate 10 by a PVD process, the seed thin film at a position where the trace pattern is located is provided on the first surface of the base substrate 10, and the seed thin film in a region except the trace pattern is provided on the photoresist layer. Subsequently, a conductive layer is formed on the seed thin film on the first surface of the base substrate 10 by an additive electroplating process, and the conductive layer is higher than the photoresist layer. By means of the CMP process and using the photoresist layer as a cut-off layer, the conductive layer and the seed thin film on the photoresist layer are completely removed, to form a first conductive layer on the first surface of the base substrate 10. The first conductive layer may at least include a first connecting electrode 41, the first connecting electrode 41 is simultaneously connected to the first conductive column 31 and the second conductive column 32, as shown in FIG. 22B.

(c3) Forming a protection layer. A first protective thin film is spin-coated on the first surface of the base substrate 10 by a spin-coating process to form a protection layer 11 covering the first conductive layer, as shown in FIG. 16.

Thus, the preparation of the filter of the present embodiment is completed, and the main body structure of the filter of the present embodiment is basically the same as that of the foregoing embodiment, except that the cross-sectional shape of the conductive column in the base substrate of the present embodiment is a column shape or a tapered shape.

The filter of the present embodiment not only has the advantages of the foregoing embodiment, but also, compared with the hourglass-shaped hole in the base substrate of the foregoing embodiment, the column-shaped hole or the tapered-shaped hole of the present embodiment can effectively reduce stress accumulation in the hole, can effectively control warpage and debris caused by stress, reduce process difficulty, improve yield, and maximize the consistency of the overall performance of the filter.

FIG. 23 is a schematic diagram of a structure of yet another filter according to an exemplary embodiment of the present disclosure. The main body structure of the filter of the present embodiment is substantially the same as that of the embodiment shown in FIG. 10, except that the first plate of the capacitor structure of the present embodiment is prepared by a patterning process. As shown in FIG. 23, the main body structure of the filter according to the exemplary embodiment of the present disclosure may include a base substrate 10, a first structure layer 100, and a second structure layer 200. The first structure layer 100 may be provided on a first surface of the base substrate 10, and the second structure layer 200 may be provided on a second surface of the base substrate 10. In an exemplary implementation, the structures of the connecting electrodes in the base substrate 10, the first structure layer 100, and the second structure layer 200 are basically the same as those in the embodiment shown in FIG. 10, and will not be repeated here.

In an exemplary implementation, the capacitor structure in the second structure layer 200 may include a first plate 51 provided on the second surface of the base substrate 10, a capacitor dielectric layer 53 provided on a side of the first plate 51 away from the base substrate, and a second plate 52 provided on a side of the capacitor dielectric layer 53 away from the base substrate. The first plate 51 may be prepared and formed by a patterning process.

In an exemplary implementation, the thickness of the first plate 51 is h1, the thickness of the third connecting electrode 43, the fourth connecting electrode 44, and the fifth connecting electrode 45 is h2, and h1 is less than h2.

In an exemplary implementation, the first plate 51 may include a seed layer, a conductive layer, and a conductive protection layer that are stacked. The seed layer may include a titanium layer, the thickness of the titanium layer is 10 nm to 200 nm, the material of the conductive layer may include aluminum, and the material of the conductive protection layer may include titanium, thus forming a sandwich stacked structure of Ti/Al/Ti.

In an exemplary implementation, the thickness of the aluminum layer may be less than 1 μm. For example, the thickness of the aluminum layer may be about 0.5 μm to 0.9 μm.

In an exemplary implementation, the material of the capacitor dielectric layer 53 may adopt silicon nitride (SiNx), and the thickness of the capacitor dielectric layer 53 may be 100 nm to 200 nm.

In an exemplary implementation, the material of the second plate 52 includes Al, the thickness of the second plate 52 may be greater than or equal to 400 nm, or the second plate 52 may adopt a sandwich stacked structure of Ti/Al/Ti.

In an exemplary implementation, the connecting electrode and the first plate 51 in the second structure layer are respectively formed by different patterning processes. Preparing and forming the first plate 51 by a patterning process may include: after forming a third connecting electrode 43, a fourth connecting electrode 44, and a fifth connecting electrode 45 of the second structure layer 200, sequentially depositing a Ti layer, an Al layer, and a Ti layer on the second surface of the base substrate 10 by a PVD process, coating a photoresist, exposing and developing the photoresist, forming the first plate 51 by a dry etching process, and finally stripping the remaining photoresist. Since the thickness of the Al layer in the first plate 51 is small and the patterning is performed by the dry etching process, the first plate 51 has good thickness uniformity and surface smoothness, and the capacitance uniformity of the capacitor structure can be effectively improved. In addition, since the patterning process is adopted, the overall process difficulty can be reduced on the premise of ensuring the flatness of the first plate, so that the production time and the production cost can be reduced.

In an exemplary implementation, the first insulating layer 61 may be provided with a plurality of first vias and a plurality of third vias, a first lead 71 may be connected to the third connecting electrode 43 through the plurality of first vias, and a third lead 73 may be connected to the second plate 52 through the plurality of third vias. By providing the plurality of vias and adopting a multi-contact via lapping mode, the contact resistance can be effectively reduced, the connection reliability can be effectively improved, the capacitor performance is improved, the capacitor loss is reduced, the probability of defects occurred in process is reduced, and the yield is improved.

The structure and the preparation process of the filter in the exemplary embodiments of the present disclosure are illustrative merely. In an exemplary implementation, corresponding structures may be changed and patterning processes may be added or reduced according to actual needs, which are not limited in the present disclosure.

A preparation method for a filter is further provided in an exemplary embodiment of the present disclosure, so as to manufacture the filter in the foregoing embodiments. In an exemplary implementation, the preparation method for the filter may include: forming a metallized through-hole base substrate, wherein a conductive column penetrating through the base substrate in a thickness direction is provided in the base substrate; and forming a first structure layer on a first surface of the base substrate, and forming a second structure layer, a first insulating layer provided on a side of the second structure layer away from the base substrate, a lead layer provided on a side of the first insulating layer away from the base substrate, a second insulating layer provided on a side of the lead layer away from the base substrate and a pad layer provided on a side of the second insulating layer away from the base substrate on a second surface of the base substrate. The first surface and the second surface are surfaces opposite to each other, the first structure layer and the second structure layer each include a connecting electrode connected to the conductive column, and the second structure layer further includes a capacitor structure. The lead layer includes at least one lead, the lead is connected to the capacitor structure, the pad layer includes at least one pad, and the pad is connected to the lead. Materials of the first insulating layer and the second insulating layer include an organic material.

In an exemplary implementation, the capacitor structure includes a first plate provided on the second surface of the base substrate, a capacitor dielectric layer provided on a side of the first plate away from the base substrate, and a second plate provided on a side of the capacitor dielectric layer away from the base substrate. An orthographic projection of the second plate on the base substrate is within a range of an orthographic projection of the capacitor dielectric layer on the base substrate, and the orthographic projection of the capacitor dielectric layer on the base substrate is within a range of an orthographic projection of the first plate on the base substrate.

In an exemplary implementation, the first plate and the connecting electrode in the second structure layer are provided in a same layer and are synchronously formed by a same patterning process.

In an exemplary implementation, the first plate and the connecting electrode in the second structure layer are provided in a same layer and are synchronously formed by a same Damascene process.

In an exemplary implementation, the first plate and the connecting electrode in the second structure layer are formed using different patterning processes, and a thickness of the first plate is less than a thickness of the connecting electrode in the second structure layer.

In an exemplary implementation, the capacitor dielectric layer and the second plate are formed using a patterning process including a dry etching process.

Another preparation method for a filter is further provided in an exemplary embodiment of the present disclosure, so as to manufacture the filter in the foregoing embodiments. In an exemplary implementation, the preparation method for the filter may include: forming a metallized blind via base substrate, wherein a conductive column not penetrating through the base substrate in a thickness direction is provided in the base substrate; forming a second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate on a second surface of the base substrate; flipping the base substrate and thinning a first surface of the base substrate until the conductive column is exposed, wherein the first surface and the second surface are surfaces opposite to each other; and forming a first structure layer on the first surface of the base substrate.

The first structure layer and the second structure layer each include a connecting electrode connected to the conductive column, the second structure layer further includes a capacitor structure, the lead layer includes at least one lead, the lead is connected to the capacitor structure, the pad layer includes at least one pad, and the pad is connected to the lead. Materials of the first insulating layer and the second insulating layer include an organic material.

The present disclosure also provides an electronic device including the filter in the foregoing embodiments. The electronic device can be used in a radio frequency front-end apparatus in a wireless communication apparatus, such as a radio frequency filter.

Although implementations of the present disclosure are disclosed above, contents described are only implementations used for ease of understanding of the present disclosure, but not intended to limit the present disclosure. Those skilled in the art may make any modification and change in the forms and details of the implementations without departing from the essence and scope of the present disclosure. However, the scope of protection of the present disclosure should still be subject to the scope defined by the attached claims.

1. A filter, comprising a base substrate, wherein:
a conductive column penetrating through the base substrate in a thickness direction is provided in the base substrate,
a first structure layer is provided on a first surface of the base substrate,
a second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate are provided on a second surface of the base substrate;
wherein the first surface and the second surface are surfaces opposite to each other; the first structure layer and the second structure layer each comprise a connecting electrode connected to the conductive column, the second structure layer further comprises a capacitor structure; the lead layer comprises at least one lead, wherein the lead is connected to the capacitor structure; the pad layer comprises at least one pad, wherein the pad is connected to the lead; materials of the first insulating layer and the second insulating layer comprise an organic material.

2. The filter of claim 1, wherein the capacitor structure comprises a first plate provided on the second surface of the base substrate, a capacitor dielectric layer provided on a side of the first plate away from the base substrate, and a second plate provided on a side of the capacitor dielectric layer away from the base substrate; an orthographic projection of the second plate on the base substrate is within a range of an orthographic projection of the capacitor dielectric layer on the base substrate.

3. The filter of claim 2, wherein the orthographic projection of the capacitor dielectric layer on the base substrate is within a range of an orthographic projection of the first plate on the base substrate.

4. The filter of claim 3, wherein areas of the first plate, the capacitor dielectric layer, and the second plate sequentially decrease along a direction away from the base substrate.

5. The filter of claim 3, wherein in a plane parallel to the base substrate, there is a first distance between an edge of the first plate and an edge of the capacitor dielectric layer in at least one direction, and the first distance is greater than or equal to 50 nm; or
wherein in a plane parallel to the base substrate, there is a second distance between an edge of the capacitor dielectric layer and an edge of the second plate in at least one direction, and the second distance is greater than or equal to 50 nm.

6. (canceled)

7. The filter of claim 2, wherein the first plate comprises a seed layer provided on the second surface of the base substrate and a conductive layer provided on a side of the seed layer away from the base substrate; the connecting electrode in the second structure layer comprises a seed layer provided on the second surface of the base substrate and a conductive layer provided on a side of the seed layer away from the base substrate.

8. The filter of claim 7, wherein the seed layer comprises a two-layer structure of a titanium layer and a copper layer, and a thickness of the titanium layer is 10 nm to 200 nm.

9. The filter of claim 7, wherein the first plate and the connecting electrode in the second structure layer are provided in a same layer and are synchronously formed by a same patterning process; or
wherein an orthographic projection of the connecting electrode in the second structure layer on the base substrate is within the range of the orthographic projection of the capacitor dielectric layer on the base substrate.

10. (canceled)

11. The filter of claim 2, wherein the first plate comprises a seed layer provided on the second surface of the base substrate, a conductive layer provided on a side of the seed layer away from the base substrate, and a conductive protection layer provided on a side of the conductive layer away from the base substrate; the connecting electrode in the second structure layer comprises a seed layer provided on the second surface of the base substrate, a conductive layer provided on a side of the seed layer away from the base substrate, and a conductive protection layer provided on a side of the conductive layer away from the base substrate.

12. The filter of claim 11, wherein the seed layer comprises a two-layer structure of a titanium layer and a copper layer, a material of the conductive protection layer comprises titanium, and a thickness of the titanium layer is 10 nm to 200 nm.

13. The filter of claim 11, wherein the first plate and the connecting electrode are provided in a same layer and are synchronously formed by a same Damascene process; or
wherein the first plate and the connecting electrode are formed by different patterning processes, and a thickness of the first plate is less than a thickness of the connecting electrode.

14. (canceled)

15. The filter of claim 2, wherein the second plate adopts a stacked structure of titanium layer/copper layer/titanium layer, or adopts a stacked structure of titanium layer/aluminum layer/titanium layer; and
wherein a thickness of the titanium layer is 30 nm to 50 nm, and a thickness of the copper layer or the aluminum layer is 200 nm to 400 nm.

16. (canceled)

17. The filter of claim 1, wherein the connecting electrode in the first structure layer comprises a seed layer and a conductive layer provided on a side of the seed layer away from the base substrate, the seed layer comprises a two-layer structure of a titanium layer and a copper layer, and a thickness of the titanium layer is 10 nm to 200 nm; and
wherein the first structure layer further comprises a protection layer provided on a side of the connecting electrode away from the base substrate, a material of the protection layer comprises an organic material, and a thickness of the protection layer is 1 μm to 10 μm.

18. (canceled)

19. The filter of claim 1, wherein a cross-sectional shape of the conductive column comprises a column shape, a tapered shape, or an hourglass shape in a direction perpendicular to the base substrate.

20. An electronic device comprising the filter of claim 1.

21. A preparation method for a filter, comprising:
forming a metallized through-hole base substrate, wherein a conductive column penetrating through the base substrate in a thickness direction is provided in the base substrate;
forming a first structure layer on a first surface of the base substrate; and
forming a second structure layer, a first insulating layer provided on a side of the second structure layer away from the base substrate, a lead layer provided on a side of the first insulating layer away from the base substrate, a second insulating layer provided on a side of the lead layer away from the base substrate and a pad layer provided on a side of the second insulating layer away from the base substrate on a second surface of the base substrate,
wherein the first surface and the second surface are surfaces opposite to each other, the first structure layer and the second structure layer each comprise a connecting electrode connected to the conductive column, the second structure layer further comprises a capacitor structure, the lead layer comprises at least one lead, the lead is connected to the capacitor structure, the pad layer comprises at least one pad, and the pad is connected to the lead; materials of the first insulating layer and the second insulating layer comprise an organic material.

22. The preparation method of claim 21, wherein the capacitor structure comprises a first plate provided on the second surface of the base substrate, a capacitor dielectric layer provided on a side of the first plate away from the base substrate, and a second plate provided on a side of the capacitor dielectric layer away from the base substrate; an orthographic projection of the second plate on the base substrate is within a range of an orthographic projection of the capacitor dielectric layer on the base substrate, and the orthographic projection of the capacitor dielectric layer on the base substrate is within a range of an orthographic projection of the first plate on the base substrate.

23. The preparation method of claim 22, wherein the first plate and the connecting electrode in the second structure layer are provided in a same layer and are synchronously formed by a same patterning process; or
wherein the first plate and the connecting electrode in the second structure layer are provided in a same layer and are synchronously formed by a same Damascene process.

24. (canceled)

25. The preparation method of claim 22, wherein the first plate and the connecting electrode in the second structure layer are formed by different patterning processes, and a thickness of the first plate is less than a thickness of the connecting electrode in the second structure layer; or
wherein the capacitor dielectric layer and the second plate are respectively formed using a patterning process comprising a dry etching process.

26. (canceled)

27. A preparation method for a filter, comprising:
forming a metallized blind via base substrate, wherein a conductive column not penetrating through the base substrate in a thickness direction is provided in the base substrate;
forming a second structure layer, a first insulating layer provided on a side of the second structure layer away from the base substrate, a lead layer provided on a side of the first insulating layer away from the base substrate, a second insulating layer provided on a side of the lead layer away from the base substrate, and a pad layer provided on a side of the second insulating layer away from the base substrate on a second surface of the base substrate;
flipping the base substrate and thinning a first surface of the base substrate until the conductive column is exposed, wherein the first surface and the second surface are surfaces opposite to each other; and
forming a first structure layer on the first surface of the base substrate;
wherein the first structure layer and the second structure layer each comprise a connecting electrode connected to the conductive column, the second structure layer further comprises a capacitor structure, the lead layer comprises at least one lead, the lead is connected to the capacitor structure, the pad layer comprises at least one pad, and the pad is connected to the lead; materials of the first insulating layer and the second insulating layer comprise an organic material.
